(19) United States
(12) Patent Application Publication
(10) Pub. No.: US 2016/0187737 A1
(43) Pub. Date: Jun. 30, 2016

(54) ARRAY SUBSTRATE, DISPLAY PANEL AND DISPLAY DEVICE

(71) Applicants: Xiamen Tianma Micro-Electronics Co., Ltd., Xiamen (CN); Tianma Micro-Electronics Co., Ltd., Shenzhen (CN)

(72) Inventors: Zhihua Dai, Xiamen (CN); Ting Zhou, Xiamen (CN); Qiong Song, Xiamen (CN); Poping Shen, Xiamen (CN); Chang-ho Tseng, Xiamen (CN)

(21) Appl. No.: 14/852,437

(22) Filed: Sep. 11, 2015

(30) Foreign Application Priority Data
Dec. 30, 2014 (CN) 201410839597.9

(51) Int. Cl. G02F 1/1343; G02F 1/1337; H01L 27/12

(52) U.S. Cl. CPC G02F 1/134309; H01L 27/1214; G02F 1/1337

(57) ABSTRACT

An array substrate, including: a plurality of pixel units; an alignment layer covering the pixel units and having an alignment direction parallel to a plane of the array substrate; and a first electrode and a second electrode both disposed within each of the pixel units; where, the first electrode has at least one branch electrode, the branch electrode has a first straight portion and a second straight portion having an end connected with the first straight portion, the first straight portion and the second straight portion are inclined inversely with respect to a direction perpendicular to the alignment direction, and an angle formed between the first straight portion and the alignment direction is larger than or equal to 5° and smaller than or equal to 8°.

### CROSS-REFERENCE TO RELATED APPLICATION

This application claims priority to Chinese Application No. 201410839597.9, filed Dec. 30, 2014, which is herein incorporated by reference in its entirety.

### TECHNICAL FIELD

The present disclosure relates to the field of flat display panel technologies and, in particular, to an array substrate, a display panel and a display device.

### BACKGROUND

In the field of liquid crystal display technologies, within an In-Plane Switching display panel which is different from a Twisted Nematic (TN) display panel where liquid crystal molecules are arranged vertically, a planar electric field is generated between electrodes of pixels in the same plane so that alignment liquid crystal molecules between the electrodes and those right over the electrodes can be rotated to a direction parallel to the plane of the substrate, thereby improving light transmittance of a liquid crystal layer. Moreover, if the liquid crystal molecules are subjected to an ambient pressure, the liquid crystal molecules slightly sink downward but are almost still maintained in the same plane overall, and hence images displayed by the display panel will not suffer from distortion and color degradation, thereby preventing the effect of the displayed images from being impaired. Due to its advantages such as a fast response speed, a large viewable angle, ripple-free touch, and real color presentation, the In-Plane Switching display panel has been widely applied in various fields.

As shown in FIG. 1, a pixel unit of an conventional In-Plane Switching display panel includes a common electrode 101 and a pixel electrode 102 which are disposed over one another, and an insulation layer (not shown) disposed between the common electrode 101 and the pixel electrode 102, where the common electrode 101 has a plurality of strip branch electrodes 103, each of which includes a first straight portion 1031 and a second straight portion 1032 which are connected with and inclined inversely from each other. When a voltage is applied across the common electrode 101 and the pixel electrode 102, a planar electric field can be formed between the common electrode 101 and the pixel electrode 102 to control rotation of the liquid crystal molecules.

FIG. 2 is a partially enlarged view of the In-Plane Switching display panel shown in FIG. 1 at a position a. With reference to FIG. 2, a first electric field E1 is formed between the pixel electrode 102 and the branch electrode 103 of the common electrode 101, so that the liquid crystal molecules 100a are rotated, under the effect of the first electric field E1, from the respective initial alignment directions (i.e. directions of macro-axes of liquid crystal molecules represented by solid lines) to a direction parallel to the direction of the first electric field E1. However, at a joint where the first straight portion 1031 and the second straight portion 1032 of the common electrode 103 are connected with each other, the liquid crystal molecules are subjected to the control of a second electric field E2 having a direction different from that of the first electric field E1. Also, such second electric fields E2 close to the joint have different directions, so that the liquid crystal molecules have different rotation directions when they are rotated from the respective initial alignment directions to directions parallel to the directions of the second electric fields E2 under the effect of the second electric fields E2 having different directions. As shown in FIG. 2, for example, the liquid crystal molecule 100b-1 is rotated to the right, but the liquid crystal molecule 100b-2 is not rotated substantially. Additionally, since the liquid crystal molecules are subjected to the control of both the first electric field E1 and the second electric field E2 at the joint, arrangement of these liquid crystal molecules may be further disordered at such joint and hence form black disclination lines at the joint. In this case, if an external force is applied to a surface of the display panel and a slide operation is performed on the surface, the arrangement of the liquid crystal molecules is more disordered, resulting in an increase of a black disclination line region at edge positions of the pixel unit, a decrease of light transmittance of the pixel unit and a reduction of luminance of the pixel unit, leading to nonuniform display and trace Mura in the display panel.

### SUMMARY

In view of the above problems, embodiments of the disclosure provide an array substrate, including: a plurality of pixel units; an alignment layer covering the pixel units and having an alignment direction parallel to a plane of the array substrate; and a first electrode and a second electrode both disposed within each of the pixel units; where, the first electrode has at least one branch electrode, the branch electrode has a first straight portion and a second straight portion having an end connected with the first straight portion, the first straight portion and the second straight portion are inclined inversely with respect to a direction perpendicular to the alignment direction, and an angle formed between the first straight portion and the alignment direction is larger than or equal to 5° and smaller than or equal to 8°.

Embodiments of the disclosure further provide a display panel, including the array substrate described above, an opposite substrate disposed opposite to the array substrate, and a liquid crystal layer disposed between the array substrate and the opposite substrate.

Embodiments of the disclosure further provide a display device, including the display panel described above.

In the case that the angle formed between the end portion electrode of the pixel unit and the alignment direction is designed to be larger than or equal to 5° and smaller than or equal to 8°, when the liquid crystal molecules are subjected to the external pressing force, the angle by which the liquid crystal molecules are rotated from the initial status back to normal display status is small, and thus recovery time of the black disclination line region at the joint where the first straight portion and the second straight portion of the branch electrode are connected with each other is also reduced, thereby effectively solving the problem of the nonuniform display and trace Mura in the displayed image.

While multiple embodiments are disclosed, still other embodiments of the disclosure will become apparent to those skilled in the art from the following detailed description, which shows and describes illustrative embodiments of the disclosure. Accordingly, the drawings and detailed description are to be regarded as illustrative in nature and not restrictive.

### BRIEF DESCRIPTION OF THE DRAWINGS

In order to more clearly illustrate the technical solutions of the disclosure, the drawings used for the description of the disclosure are briefly introduced below. Obviously, the drawings for the following description only show some embodiments, and other drawings may also be obtained from the described drawings.

FIG. 1 is a schematic diagram showing the structure of a pixel unit of an In-Plane Switching display panel provided in the related art;

FIG. 2 is a partially enlarged view showing arrangement of liquid crystal molecules of the pixel unit shown in FIG. 1 at a position a;

FIG. 3 is a schematic diagram showing the structure of a pixel unit of an array substrate, according to embodiments of the disclosure;

FIG. 4 is a sectional diagram of the array substrate shown in FIG. 3 taken along a section line A-A′;

FIG. 5 is a schematic diagram showing the structure of the branch electrode of the pixel electrode in a position b shown in FIG. 3;

FIG. 6 is a schematic diagram illustrating the control of an electric field of the first straight portion of the pixel electrode, according to embodiments shown in FIG. 3;

FIG. 7 is a graph showing trace Mura recovery time and light transmittance of the display panel versus the angle between the first straight portion electrode and the alignment direction, according to embodiments of the disclosure;

FIG. 8 is a schematic diagram showing the structure of a pixel unit of another array substrate, according to embodiments of the disclosure;

FIG. 9 is a schematic diagram showing the structure of the branch electrode of the pixel electrode in a position c shown in FIG. 8;

FIG. 10 is a schematic diagram showing the structure of a pixel unit of another array substrate, according to embodiments of the disclosure;

FIG. 11 is a sectional diagram of the array substrate shown in FIG. 10 taken along a sectional line B-B′;

FIG. 12 is a schematic diagram showing the structure of the branch electrode of the pixel electrode in a position d shown in FIG. 10;

FIG. 13 is a sectional diagram of the structure of a display panel, according to embodiments of the disclosure; and

FIG. 14 is a sectional diagram of the structure of a display device, according to embodiments of the disclosure.

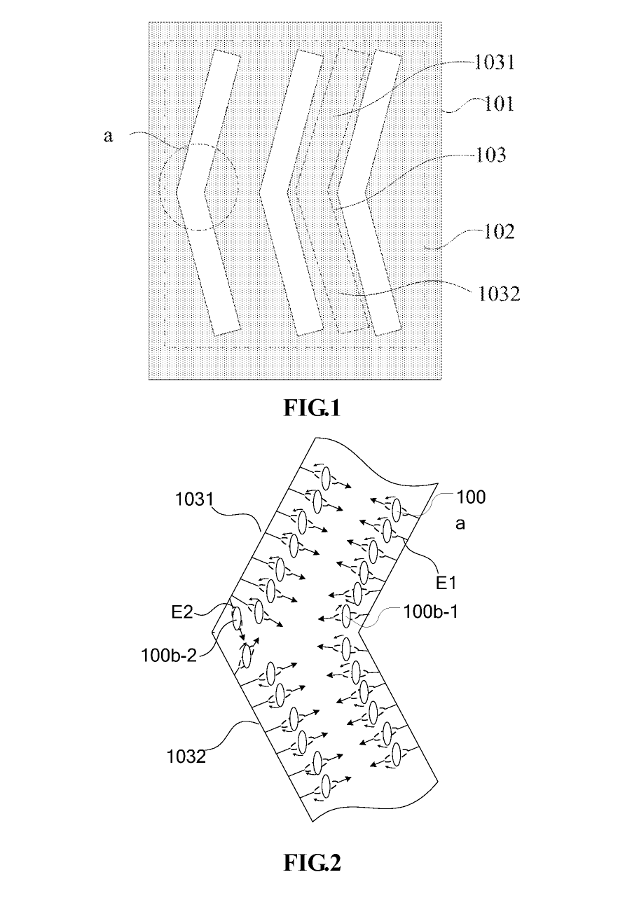

While the disclosure is amenable to various modifications and alternative forms, embodiments have been shown by way of example in the drawings and are described in detail below. The intention, however, is not to limit the disclosure to the embodiments described. On the contrary, the disclosure is intended to cover all modifications, equivalents, and alternatives falling within the scope of the disclosure as defined by the appended claims.

### DETAILED DESCRIPTION

The technical solutions in the disclosure are clearly and completely described below in combination with the drawings. Obviously, the described embodiments are some instead of all embodiments of the disclosure. All other embodiments obtained in light of the described embodiments of the disclosure fall within the protection scope of the disclosure.

Embodiments of the disclosure provide an array substrate, including a plurality of gate lines and a plurality of data lines, where, a plurality of pixel units are defined by insulatively intersecting the gate lines with the data lines, and a thin film transistor is disposed at an intersection between the gate line and the data line and is further electrically connected with the gate line and the data line. The pixel units can be arranged in an array or arranged in a staggered manner. The pixel units are covered by an alignment layer having an alignment direction parallel to a plane of the array substrate. A first electrode and a second electrode both are disposed within the pixel unit, where, the first electrode and the second electrode can generate a planar electric field to control rotation of the liquid crystal molecules, the first electrode has at least one branch electrode which has a first straight portion and a second straight portion having an end connected with the first straight portion, the first straight portion and the second straight portion are inclined inversely with respect to a direction perpendicular to the alignment direction, and an angle formed between the first straight portion and the alignment direction is larger than or equal to 5°, and smaller than or equal to 8°. The angle formed between the first straight portion and the alignment direction refers to an angle between an extension direction of the first straight portion parallel to the array substrate and an alignment direction of the alignment layer parallel to the array substrate. The first electrode may be a pixel electrode and the second electrode may be a common electrode, or the first electrode may be a common electrode and the second electrode may be a pixel electrode.

In an Fringe Field Switching (FFS) display mode, the first electrode and the second electrode can be located at different layers, i.e. the first electrode and the second electrode are insulatively stacked over one another, and in this case, a fringe electric field is formed between the first electrodes and the second electrodes so that alignment liquid crystal molecules between the electrodes and those right over the electrodes can be rotated to directions parallel to the plane of the substrate, thereby improving light transmittance of a liquid crystal layer. In an In-Plane Switching (IPS) display mode, the first electrode and the second electrode may be located at different layers or at the same layer, where, each of the first electrode and the second electrode includes a plurality of branch electrodes, the branch electrodes of the first electrode are arranged alternately with and spaced from the branch electrodes of the second electrode, and in this way, an electric field parallel to the array substrate is formed between the first electrode and the second electrode to control rotation of the liquid crystal molecules so as to display a image with an better angle of view.

In order to make the technical solutions provided in the disclosure more clear, the first electrode is illustratively described as a pixel electrode and the second electrode is illustratively described as a common electrode in the FFS display mode below.

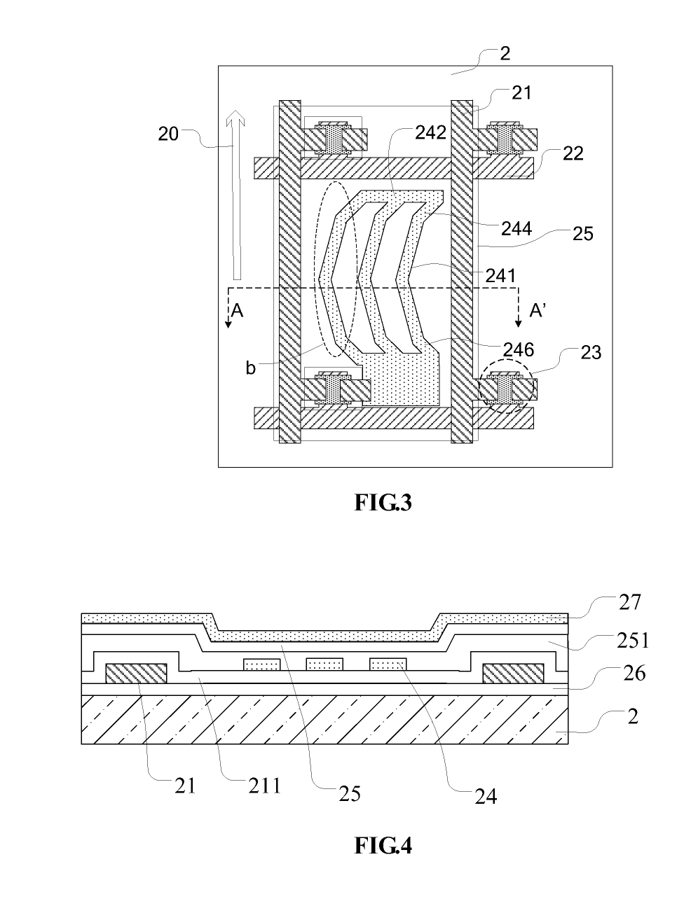

FIG. 3 is a schematic diagram showing the structure of a pixel unit of an array substrate, according to embodiments of the disclosure, and FIG. 4 is a sectional diagram of the array substrate shown in FIG. 3 taken along a section line A-A′. As shown in FIG. 3, the array substrate 2 includes a plurality of gate lines 22 and a plurality of data lines 21, where, a plurality of pixel units are defined by insulatively intersecting the gate lines 22 with the data lines 21, and a thin film transistor 23 is disposed at an intersection between the gate line 22 and the data lines 21 and is further electrically connected with the gate line 22 and data line 21. The pixel units can be arranged in an array or arranged in a staggered manner. In embodiments, illustratively, one of the pixel units will be described to explain the structure thereof.

With reference to FIG. 4, the array substrate includes an underneath substrate 2, where, the underneath substrate 2 may be a glass substrate or a flexible resin substrate. A gate insulation layer 26 covering the gate lines 22 is disposed on the underneath substrate 2, the data lines 21 are disposed on the gate insulation layer 26, an insulation layer 211 is disposed to cover the data lines 21 and the gate insulation layer 26, and a pixel electrode 24 is disposed on the insulation layer 211 and electrically connected with a drain electrode of the thin film transistor 23 via a via hole (not shown) in the insulation layer 211. The pixel electrode 24 includes at least one branch electrode 241. In embodiments, the pixel electrode 24 includes three branch electrodes 241, and end portions of the plurality of branch electrodes 241 are connected with a connection electrode 242 so that a data signal can be transmitted to each of the branch electrodes 241. An interlamination insulation layer 251 is disposed to cover the pixel electrode 24 and the insulation layer 211, an entire common electrode 25 is disposed on the interlamination insulation layer 251, and a fringe electric field can be formed between the common electrode 25 and the pixel electrode 24. The common electrodes 25 of the plurality of pixel units can be electrically connected together with each other and connected to a peripheral circuit via wirings in order to receive a common electrode signal. An alignment layer 27 is disposed on the common electrode 25 and covers the pixel unit, and has an alignment direction 20 parallel to the plane of the array substrate. In the case of liquid crystal molecules having a negative dielectric anisotropy, the alignment direction is generally perpendicular to an extension direction of the branch electrode. In FIGS. 3 and 4, illustratively, liquid crystal molecules having a positive dielectric anisotropy are employed, and the alignment direction 20 is generally parallel to the extension direction of the branch electrode 241.

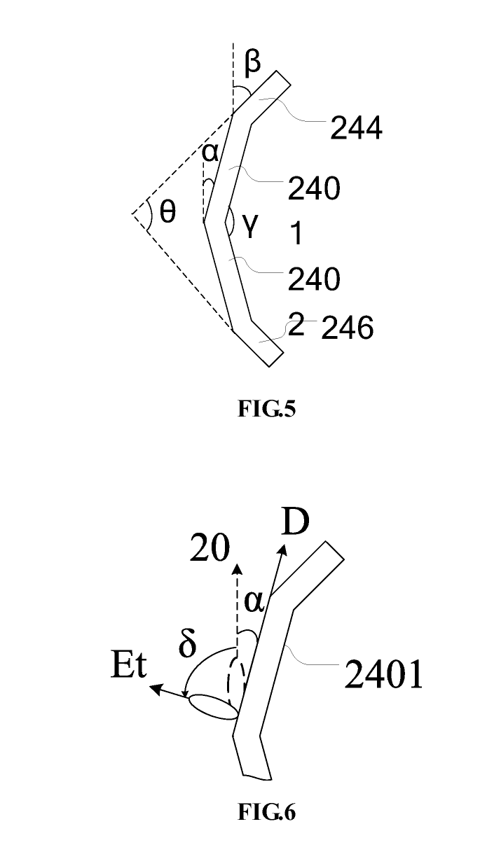

FIG. 5 is a schematic diagram showing the structure of the branch electrode of the pixel electrode in a position b shown in FIG. 3, and FIG. 6 is a schematic diagram illustrating the control of an electric field of the first straight portion of the pixel electrode, according to embodiments shown in FIG. 3. As shown in FIG. 5, the branch electrode 241 of the pixel electrode 24 includes a first straight portion 2401 and a second straight portion 2402 having an end connected with the first straight portion 2401, and an angle of γ is formed between the first straight portion 2401 and the second straight portion 2402, i.e. a V-shaped structure is formed by the first straight portion 2401 and the second straight portion 2402. Specifically, the first straight portion 2401 and the second straight portion 2402 are inclined inversely with respect to a direction perpendicular to the alignment direction 20, i.e. the first straight portion 2401 and the second straight portion 2402 are inclined toward the direction perpendicular to the alignment direction 20, and are symmetric with respect to the direction perpendicular to the alignment direction 20. An angle of α is formed between the first straight portion 2401 and the alignment direction 20, and an angle formed between the second straight portion 2402 and the alignment direction 20 is equal to the angle formed between the first straight portion 2401 and the alignment direction 20. A first end portion 244 is disposed at the other end of the first straight portion 2401 (i.e. an end of the first straight portion 2401 that is away from the second straight portion 2402), and a second end portion 246 is disposed at the other end of the second straight portion 2402 (i.e. an end of the second straight portion 2402 that is away from the first straight portion 2401), and an angle of θ formed between an extension direction of the first end portion 244 and an extension direction of the second end portion 246 is smaller than the angle of γ formed between the first straight portion 2401 and the second straight portion 2402, i.e. θ<γ. The angle of α formed between the first straight portion 2401 and the alignment direction 20 is different from an angle of β formed between the first end portion 244 and the alignment direction 20, i.e. α≠β.

With reference to FIG. 6, it is proved that, during normal operations of the array substrate, a third electric field force Et perpendicular to an extension direction D of the first straight portion 2401 is generated at the first straight portion 2401 of the branch electrode 241 of the pixel electrode, to control rotation of the liquid crystal molecules to the direction of the third electric field force Et. However, if an external force is applied to a surface of the display panel and a slide operation is performed on the surface, the directions of electric fields become more disordered at the joint where the first straight portion 2401 and the second straight portion 2402 are connected with each other, and the combined vector direction of the directions of the electric fields is approximately parallel to the alignment direction, so that the liquid crystal molecules are rotated to the initial direction (i.e. the direction parallel to the alignment direction). Because the directions of the electric field forces are more complex at positions closer to the joint, a portion of the liquid crystal molecules are constrained, by the electric field forces with the disordered directions, to be in the initial status with the alignment direction. After the external force is removed, this portion of the liquid crystal molecules cannot be rotated back to the direction of the liquid crystal molecules in the normal display status (i.e. the direction parallel to the direction of the third electric field force). When the angle of α formed between the first straight portion 2401 and the alignment direction 20 is increased, the angle of δ formed between the third electric field force Et and the alignment direction 20 is decreased, and hence, an angle by which the liquid crystal molecules are rotated from the initial status (i.e. the direction parallel to the alignment direction) back to normal display status (i.e. the direction parallel to the direction of the third electric field force) is reduced when the external force is removed, so that the normal display status can be quickly achieved once the liquid crystal molecules are rotated by the reduced angle, and recovery time of the black disclination line region at the joint where the first straight portion 2401 and the second straight portion 2402 of the branch electrode are connected with each other can also be reduced, thereby solving the problem of the nonuniform display and trace Mura in the display image.

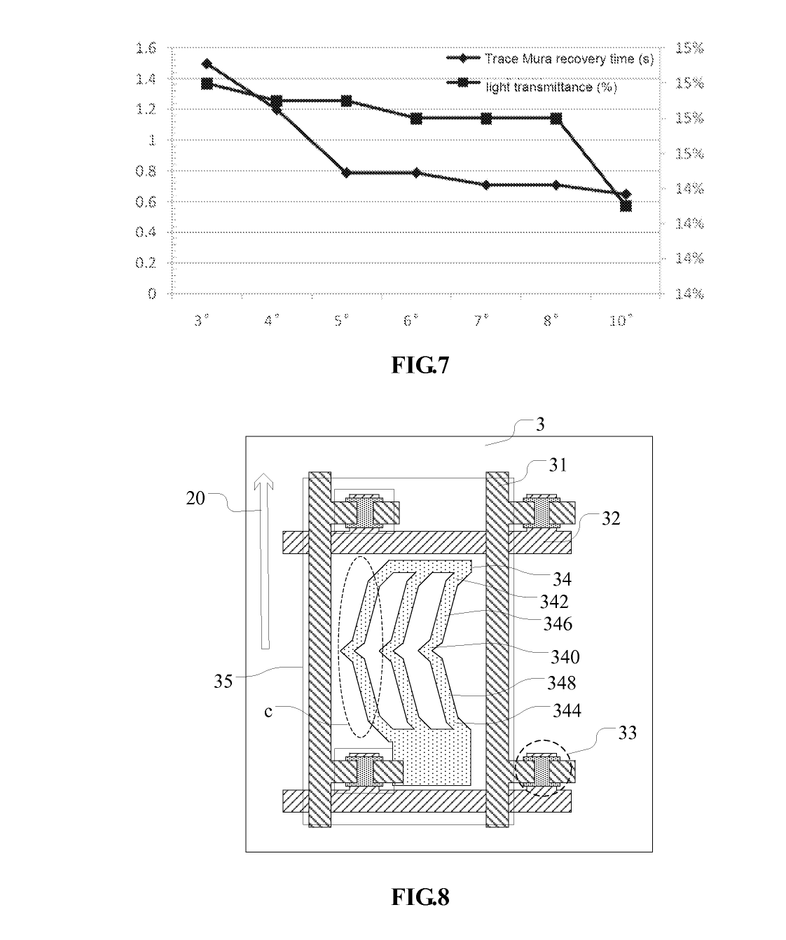

FIG. 7 is a graph showing trace Mura recovery time and light transmittance of the display panel versus the angle of α between the first straight portion electrode and the alignment direction 20 according to the embodiment of the present invention. Values of the trace Mura recovery time and light transmittance varying with the angle of α are listed in detail in Table 1:

TABLE 1

| Angle of α | Trace Mura recovery time (s) | light transmittance (%) |
|---|---|---|
| 3° | 1.50 | 15.0% |
| 4° | 1.20 | 14.9% |
| 5° | 0.79 | 14.9% |
| 6° | 0.79 | 14.8% |
| 7° | 0.71 | 14.8% |
| 8° | 0.71 | 14.8% |
| 10° | 0.65 | 14.3% |

It is indicated by the above experiment data that the trace Mura recovery time of the display panel is decreased gradually as the angle of α formed between the first straight portion 2401 of the branch electrode and the alignment direction 20 is increased gradually. When the angle of α formed between the first straight portion 2401 of the branch electrode and the alignment direction 20 is smaller than 4°, the trace Mura recovery time of the display panel is larger than 1 second (s), and the trace Mura is noticeable. However, when the angle of α formed between the first straight portion 2401 of the branch electrode and the alignment direction 20 is increased gradually to be larger than or equal to 5°, the trace Mura recovery time of the display panel is decreased to be below 1 s or even below 0.8 s, and in this case, after the external force is applied to the display panel and a slide operation is performed on the surface, the display panel can quickly recover to display a image normally, thereby effectively solving the problem of the nonuniform display and trace Mura, furthermore, the trace Mura recovery time is relatively stable and will not vary dramatically with the variation of the angel of α, thus the angel of α larger than or equal to 5° is suitable for the mass production process.

It is noted that, since the angle of α formed between the first straight portion 2401 of the branch electrode and the alignment direction 20 can further affect the light transmittance of the display panel, the angle of α cannot be excessively large. It can be known from Table 1 and FIG. 7 that the light transmittance of the display panel is decreased rapidly when the angle of α is larger than 8°, and the light transmittance of the display panel is even decreased to 14.5% when the angle of α is larger than 10°, so that luminance of the image displayed by the display panel will be significantly affected. Therefore, the angle of α formed between the first straight portion 2401 of the branch electrode and the alignment direction 20 can be designed to be larger than or equal to 5° and smaller than or equal to 8° considering the light transmittance of the display panel under the precondition of alleviating the trace Mura. As such, the nonuniform display and the trace Mura in the display panel can be effectively alleviated while the better light transmittance can be obtained. Also, the angle of α formed between the first straight portion 2401 of the branch electrode and the alignment direction 20 can be designed to be larger than or equal to 6° and smaller than or equal to 8°, which is suitable for mass production process since the light transmittance of the display panel is substantially maintained as 14.8% and will not vary significantly due to the variation of the angel.

As shown in FIG. 5, the angle formed between the second straight portion 2402 and the alignment direction 20 can be designed to be larger than or equal to 5° and smaller than or equal to 8° and, in some embodiments, can be designed to be larger than or equal to 6° and smaller than or equal to 8°. The reason is the same as that of design of the angle of α formed between the first straight portion 2401 of the branch electrode and the alignment direction 20, which is not repeated here. In the case that the angle formed between the end portion electrode within the pixel unit and the alignment direction is designed to be larger than or equal to 5° and smaller than or equal to 8°, when the liquid crystal molecules are subjected to the external pressing force, the angle by which the liquid crystal molecules are rotated from the initial status back to normal display status is small, and thus recovery time of the black disclination line region at the joint where the first straight portion and the second straight portion of the branch electrode are connected with each other is also reduced, thereby effectively solving the problem of the nonuniform display and trace Mura in the displayed image.

In embodiments, the FFS display mode is used, but the IPS display mode may also be used instead. In other embodiments, the pixel electrode 34 and the common electrode 35 may further be located at the same layer, and in this case, the branch electrodes of the pixel electrode are arranged alternately with and spaced from the branch electrodes of the common electrode. Additionally, the branch electrode 241 of the pixel electrode 24 may include the first straight portion 2401 and the second straight portion 2402, with the first end portion 244 and the second end portion 246 omitted.

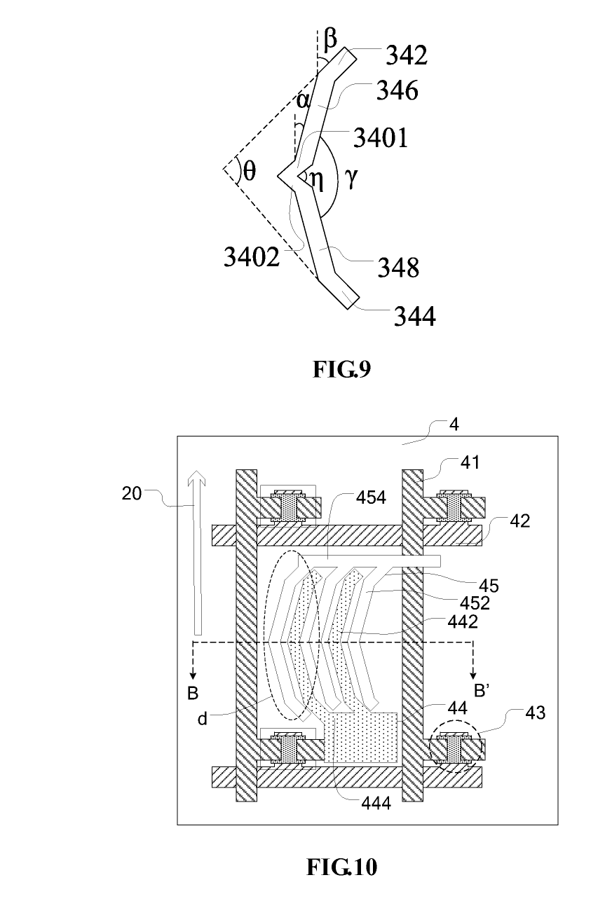

FIG. 8 is a schematic diagram showing the structure of a pixel unit of another array substrate, according to embodiments of the disclosure, and FIG. 9 is a schematic diagram showing the structure of the branch electrode of the pixel electrode in a position c shown in FIG. 8. As shown in FIG. 8, a difference between the structure of the pixel unit of FIG. 8 and that shown in FIG. 3 lies in that, the branch electrode of the pixel electrode 34 includes a first straight portion 346, a second straight portion 348, and a V-shaped portion 340 which is disposed between the first straight portion 346 and the second straight portion 348 and connects an end of the first straight portion 346 with an end of the second straight portion 348.

With reference to FIG. 9, a first end portion 342 is disposed at the other end of the first straight portion 346 (i.e. an end of the first straight portion that is away from the second straight portion), and a second end portion 344 is disposed at the other end of the second straight portion 348 (i.e. an end of the second straight portion that is away from the first straight portion), where, an angle of θ formed between an extension direction of the first end portion 342 and an extension direction of the second end portion 344 is smaller than the angle of γ formed between the first straight portion 346 and the second straight portion 348, i.e. θ<γ. The angle of α formed between the first straight portion 346 and the alignment direction 20 is different from an angle of β formed between the first end portion 342 and the alignment direction 20, i.e. a α≠β. An angle of γ is formed between the first straight portion 346 and the second straight portion 348. The first straight portion 346 and the second straight portion 348 are inclined inversely with respect to a direction perpendicular to the alignment direction 20, i.e. the first straight portion 346 and the second straight portion 348 are inclined toward the direction perpendicular to the alignment direction 20, and are symmetric with respect to the direction perpendicular to the alignment direction 20. An angle of α is formed between the first straight portion 346 and the alignment direction 20, and an angle formed between the second straight portion 348 and the alignment direction 20 is equal to the angle formed between the first straight portion 346 and the alignment direction 20.

Referring still to FIG. 9, the V-shaped portion 340 includes a first segment 3401 and a second segment 3402, where, an end of the first segment 3401 is connected with the first straight portion 346, and the other end of the first segment 3401 is connected with the second segment 3402. An angle of η is formed between the first segment 3401 and the second segment 3402. The angle of η is smaller than the angle γ formed between the first straight portion 346 and the second straight portion 348, i.e., η<γ.

The angle formed between the first straight portion 346 and the alignment direction 20 and the angle formed between the second straight portion 348 and the alignment direction 20 both are designed to be larger than or equal to 5° and smaller than or equal to 8°. When an external force is applied to a surface of the display panel and a slide operation is performed on the surface, the direction of the electric field become more disordered at the joint where the first straight portion 346 and the second straight portion 348 are connected with each other, and combination vector direction of the directions of the electric fields is approximatively parallel to the alignment direction, so the liquid crystal molecules can be rotated to initial direction (i.e. the direction parallel to the alignment direction). After the external force is removed, the angle by which the liquid crystal molecules are rotated from the initial status back to normal display status (i.e. the direction perpendicular to the first straight portion) is reduced, so that the normal display status can be quickly achieved once the liquid crystal molecules are rotated by the reduced angle, and recovery time of the black disclination line region at the first straight portion 346 and the second straight portion 348 of the branch electrode is reduced, thereby solving the problem of the nonuniform display and trace Mura in the display image. Further, the angle formed between the first straight portion 346 and the alignment direction 20 and the angle formed between the second straight portion 348 and the alignment direction 20 both can be designed to be larger than or equal to 6° and smaller than or equal to 8°. As such, the nonuniform display and the trace Mura in the display panel can be effectively alleviated while the better light transmittance can be obtained. The principle is consistent with that described in relation to FIG. 3, which is not repeated here.

In embodiments, the pixel electrode 34 and the common electrode 35 can further be located at the same layer, and in this case, the branch electrodes of the pixel electrode are arranged alternately with and spaced from the branch electrodes of the common electrode. Additionally, the branch electrode of the pixel electrode 24 may include the first straight portion 346 and the second straight portion 348, with the first end portion 342 and the second end portion 344 omitted.

FIG. 10 is a schematic diagram of the structure of a pixel unit of another array substrate, according to embodiments of the disclosure, and FIG. 11 is a sectional diagram of the array substrate shown in FIG. 10 taken along a sectional line B-B′. The first electrode is illustratively described as a pixel electrode and the second electrode is illustratively described as a common electrode in the IPS display mode below. With reference to FIGS. 10 and 11, the array substrate includes an underneath substrate 4. A gate insulation layer 411 covering the gate lines 22 is disposed on the underneath substrate 4, and the data lines 21 and the common electrode 45 are disposed on the gate insulation layer 411. The common electrode 45 includes at least one branch electrode 452. In embodiments, the common electrode 45 includes three branch electrodes 452, and end portions of the branch electrodes 452 have connection electrodes 454 connected with the plurality of branch electrodes 452. The common electrodes of the plurality of pixel units can be electrically connected together with each other and connected to a peripheral circuit via wirings in order to receive a common electrode signal. An interlamination insulation layer 451 is disposed to cover data lines 41, the common electrode 45 and the gate insulation layer 411, where, an pixel electrode 44 is disposed on the interlamination insulation layer 451 and electrically connected with a drain electrode of a thin film transistor 43 via a via hole in an insulation layer 451. The pixel electrode 44 includes at least one branch electrode 442. In embodiments, the pixel electrode 44 includes two branch electrodes 442, and one end of the branch electrode 442 of the pixel electrode has connection electrodes 444 connected with the plurality of branch electrodes 442 so that data signal can be outputted to each of the branch electrodes 442 of the pixel electrode. The projections of the branch electrodes 452 of the common electrode 45 on the underneath substrate are arranged alternately with and spaced from the projections of the branch electrodes 442 of the pixel electrode 44 on the underneath substrate, so that horizontal electric fields may be formed between the branch electrodes 452 of the common electrode 45 and the branch electrodes 442 of the pixel electrode 44. A layer 441 and an alignment layer 47 is disposed on the common electrode 45 and covers the pixel unit, and has an alignment direction 20 parallel to a plane of the array substrate. In the case of liquid crystal molecules having a negative dielectric anisotropy, the alignment direction is generally perpendicular to an extension direction of the branch electrode. In FIG. 10, illustratively, liquid crystal molecules having a positive dielectric anisotropy are employed, and the alignment direction 20 is generally parallel to the extension direction of the branch electrode 442.

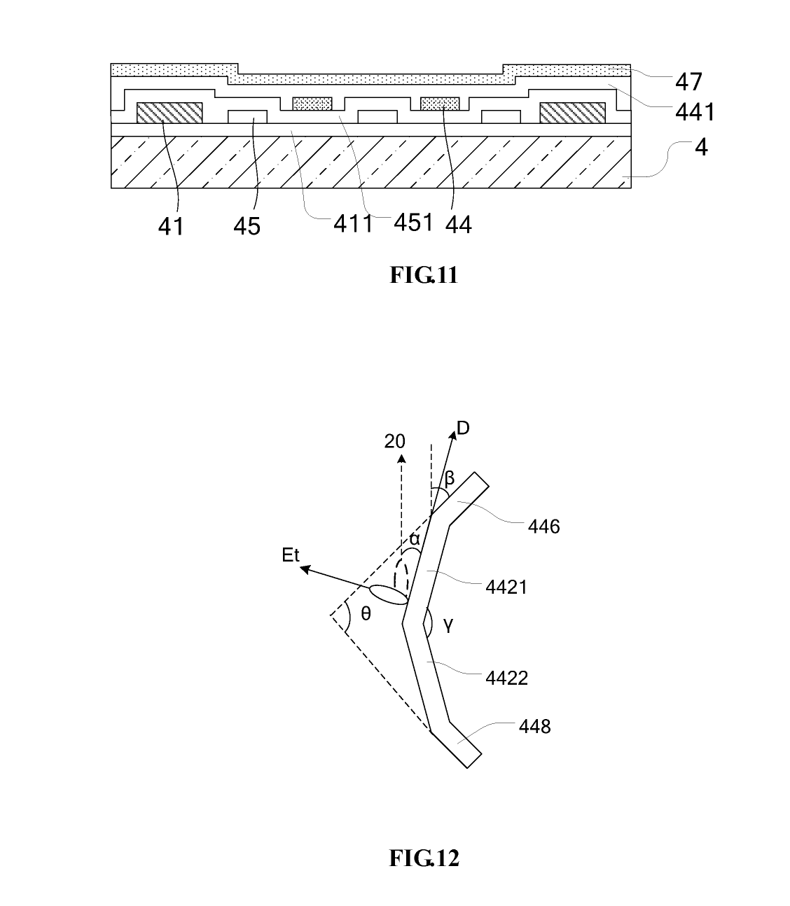

FIG. 12 is a schematic diagram showing the structure of the branch electrode of the pixel electrode in a position d shown in FIG. 10. As shown in FIG. 12, the branch electrode 442 of the pixel electrode 44 includes a first straight portion 4421 and a second straight portion 4422 having an end connected with the first straight portion 4421, and an angle of γ is formed between the first straight portion 4421 and the second straight portion 4422, i.e. a V-shaped structure is formed by the first straight portion 4421 and the second straight portion 4422. The first straight portion 4421 and the second straight portion 4422 are inclined inversely with respect to a direction perpendicular to the alignment direction 20, i.e. the first straight portion 4421 and the second straight portion 4422 are inclined toward the direction perpendicular to the alignment direction 20, and are symmetric with respect to the direction perpendicular to the alignment direction 20. An angle of α is formed between the first straight portion 4421 and the alignment direction 20, and an angle formed between the second straight portion 4422 and the alignment direction 20 is equal to the angle formed between the first straight portion 4421 and the alignment direction 20. A first end portion 446 is disposed at the other end of the first straight portion 4421, and a second end portion 448 is disposed at the other end of the second straight portion 4422, where, an angle of θ is formed between an extension direction of the first end portion 446 and an extension direction of the second end portion 448 is smaller than the angle of γ formed between the first straight portion 4421 and the second straight portion 4422, i.e. θ<γ. The angle of α formed between the first straight portion 4421 and the alignment direction 20 is different from an angle of α formed between the first end portion 446 and the alignment direction 20, i.e. α≠β.

Similar to the control by the electric field of the first straight portion of the pixel electrode shown in FIG. 6, during normal operations of the array substrate, a third electric field force Et perpendicular to an extension direction D of the first straight portion 4421 can be generated at the first straight portion 4421 of the branch electrode 442 of the pixel electrode, to control rotation of the liquid crystal molecules to the direction of the third electric field force Et. However, if an external force is applied to a surface of the display panel and a slide operation is performed on the surface, the directions of the electric fields become more disordered at the joint where the first straight portion 4421 and the second straight portion 4422 are connected with each other, and combination vector direction of the directions of the electric fields is approximately parallel to the alignment direction, so the liquid crystal molecules can be rotated to the initial direction (i.e. rotated to the direction of macro-axes of liquid crystal molecules represented by dashed lines parallel to the alignment direction). Because the directions of the electric field forces are more complex at positions closer to the joint, a portion of the liquid crystal molecules can be constrained, by the electric field forces with the disordered directions, to be in the initial status with the alignment direction. After the external force is removed, this portion of the liquid crystal molecules cannot be rotated back to the direction of the liquid crystal molecules in the normal display status (i.e. the direction of macro-axes of liquid crystal molecules represented by dashed lines parallel to the direction of the third electric field force). When the angle of α formed between the first straight portion 4421 and the alignment direction 20 is increased, the angle of δ formed between the third electric field force Et and the alignment direction 20 is decreased. The angle by which the liquid crystal molecules are rotated from the initial status (i.e. the direction of macro-axes of liquid crystal molecules represented by dashed lines parallel to the alignment direction) to normal display status (i.e. the direction of macro-axes of liquid crystal molecules represented by dashed lines parallel to the direction of the third electric field force) is reduced when the external force is removed, so that the normal display status can be quickly achieved once the liquid crystal molecules are rotated by the reduced angle, and recovery time of the black disclination line region at the joint where the first straight portion 4421 and the second straight portion 4422 of the branch electrode are connected with each other can also be reduced, thereby solving the problem of the nonuniform display and trace Mura in the display image. The control by the electric field of the first straight portion of the branch electrode of the common electrode is similar to that of the branch electrode of the pixel electrode, which is not repeated here.

In the case that the angle formed between the first straight portion 4421 and the alignment direction 20 and the angle formed between the second straight portion 4422 and the alignment direction 20 both are designed to be larger than or equal to 5° and smaller than or equal to 8°, when an external force is applied to a surface of the display panel and a slide operation is performed on the surface, the liquid crystal molecules can be rotated to the initial direction (i.e. the direction parallel to the alignment direction). The angle by which the liquid crystal molecules are rotated from the initial status to normal display status (i.e. the direction perpendicular to the first straight portion) is reduced when the external force is removed, so that the normal display status can be quickly achieved once the liquid crystal molecules are rotated by the reduced angle, and recovery time of the black disclination line region at the joint where the first straight portion and the second straight portion of the branch electrode are connected with each other can also be reduced, thereby solving the problem of the nonuniform display and trace Mura in the display image. Further, The angle formed between the first straight portion 4421 and the alignment direction 20 and the angle formed between the second straight portion 4422 and the alignment direction 20 both can be designed to be larger than or equal to 6° and smaller than or equal to 8°. As such, the nonuniform display and the trace Mura in the display panel can be effectively alleviated while the better light transmittance can be obtained.

In embodiments, the pixel electrode and the common electrode can further be located at the same layer, and in this case, the branch electrodes of the pixel electrode are arranged alternately with and spaced from the branch electrodes of the common electrode. Additionally, the branch electrode of the pixel electrode may include the first straight portion and the second straight portion, with the first end portion and the second end portion omitted.

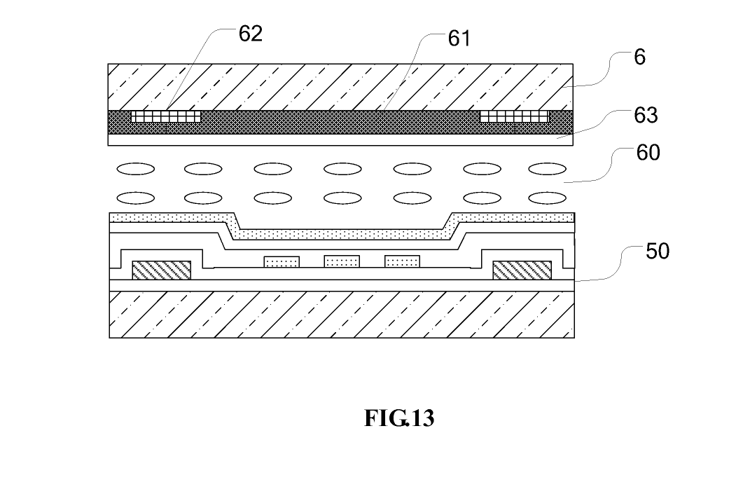

FIG. 13 is a sectional diagram of the structure of a display panel, according to embodiments of the disclosure. As shown in FIG. 13, the display panel includes: an array substrate 50 described in the above embodiments, an opposite substrate 6 disposed opposite to the array substrate 50, and a liquid crystal layer 60 disposed between the array substrate 50 and the opposite substrate 6. Black matrixes 62 are disposed on the opposite substrate 6, a color filter layer 61 is disposed between the black matrixes 62, the color filter layer 61 includes light filters for different colors, and each of the light filters corresponds to a different pixel unit. The color filter layer 61 is covered by a planarization layer. In the case that the angle formed between the end portion electrode of the pixel unit and the alignment direction is designed to be larger than or equal to 5° and smaller than or equal to 8°, when the liquid crystal molecules are subjected to the external pressing force, the angle by which the liquid crystal molecules are rotated from the initial status back to normal display status is small, and thus recovery time of the black disclination line region at the joint where the first straight portion and the second straight portion of the branch electrode are connected with each other is also reduced, thereby effectively solving the problem of the nonuniform display and trace Mura in the displayed image.

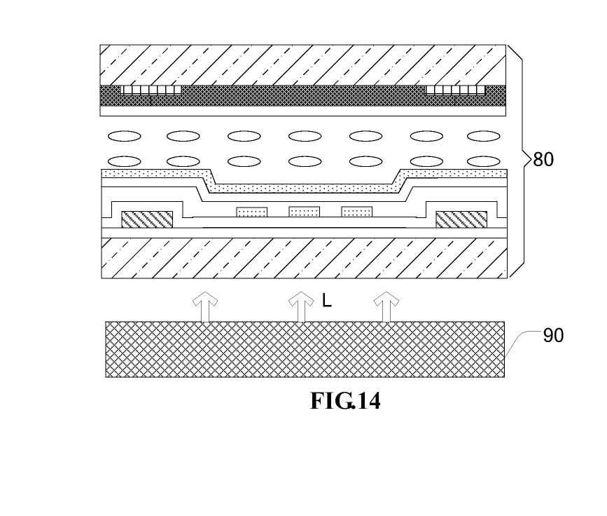

FIG. 14 is a sectional diagram of the structure of a display device, according to embodiments of the disclosure. As shown in FIG. 14, the display device includes: a display panel 80 described in the above embodiments and a light source device 90 disposed at one side of the display panel 80, where, the light source device 90 is configured to provide the display panel 80 with a light source L. In the case that the angle formed between the end portion electrode of the pixel unit and the alignment direction is designed to be larger than or equal to 5° and smaller than or equal to 8°, when the liquid crystal molecules are subjected to the external pressing force, the angle by which the liquid crystal molecules are rotated from the initial status back to normal display status is small, and thus recovery time of the black disclination line region at the joint where the first straight portion and the second straight portion of the branch electrode are connected with each other is also reduced, thereby effectively solving the problem of the nonuniform display and trace Mura in the displayed image.

The array substrate, the display panel and the display device of the disclosure are described in detail above. Principles of the disclosure and implementation thereof are illustrated by examples in the disclosure. The illustrations of the embodiments above are merely used to assist in understanding the methods of the disclosure and core ideas thereof. Meanwhile, changes can be made by those skilled in the art according to the ideas of the disclosure without departing from the scope of protection of the disclosure. The content of the specification should not be construed as limiting the disclosure.

Various modifications and additions can be made to the exemplary embodiments discussed without departing from the scope of the disclosure. For example, while the embodiments described above refer to particular features, the scope of this disclosure also includes embodiments having different combinations of features and embodiments that do not include all of the described features. Accordingly, the scope of the disclsoure is intended to embrace all such alternatives, modifications, and variations as fall within the scope of the claims, together with all equivalents thereof.

We claim:

1. An array substrate, comprising:
a plurality of pixel units;
an alignment layer covering the pixel units and having an alignment direction parallel to a plane of the array substrate; and
a first electrode and a second electrode both disposed within each of the pixel units;
wherein, the first electrode has at least one branch electrode, the branch electrode has a first straight portion and a second straight portion, the first straight portion and the second straight portion are inclined inversely with respect to a direction perpendicular to the alignment direction, and an angle formed between the first straight portion and the alignment direction is larger than or equal to 5° and smaller than or equal to 8°.

2. The array substrate of claim 1, wherein, the angle formed between the first straight portion and the alignment direction is larger than or equal to 6° and smaller than or equal to 8°.

3. The array substrate of claim 1, wherein, the second straight portion having an end connected with the first straight portion.

4. The array substrate of claim 3, further comprising a first end portion disposed at an end of the first straight portion and a second end portion disposed at an end of the second straight portion, wherein, an angle formed between an extension direction of the first end portion and an extension direction of the second end portion is smaller than the angle formed between the first straight portion and the second straight portion.

5. The array substrate of claim 1, further comprising a V-shaped portion connected with the first straight portion and the second straight portion, and an angle of the V-shaped portion is smaller than an angle formed between an extension direction of first straight portion and an extension direction of the second straight portion.

6. The array substrate of claim 5, further comprising a first end portion disposed at an end of the first straight portion away from the V-shaped portion and a second end portion disposed at an end of the second straight portion away from away from the V-shaped portion, wherein an angle formed between the alignment direction and the first end portion or the second end portion is larger than an angle formed between the alignment direction and the first straight portion or the second straight portion.

7. The array substrate of claim 1, wherein, the first electrode is a pixel electrode and the second electrode is a common electrode, or the first electrode is a common electrode and the second electrode is a pixel electrode.

8. The array substrate of claim 1, wherein, the first electrode and the second electrode are located at different layers and the second electrode has an entire planar structure.

9. The array substrate of claim 1, wherein, the second electrode has at least one branch electrode, and the at least one branch electrode of the first electrodes are arranged alternately with and spaced from the at least one branch electrode of the second electrodes.

10. A display panel, comprising an array substrate, an opposite substrate disposed opposite to the array substrate, and a liquid crystal layer disposed between the array substrate and the opposite substrate, the array substrate comprising:
a plurality of pixel units;
an alignment layer covering the pixel units and having an alignment direction parallel to a plane of the array substrate; and
a first electrode and a second electrode both disposed within each of the pixel units;
wherein, the first electrode has at least one branch electrode, the branch electrode has a first straight portion and a second straight portion, the first straight portion and the second straight portion are inclined inversely with respect to a direction perpendicular to the alignment direction, and an angle formed between the first straight portion and the alignment direction is larger than or equal to 5° and smaller than or equal to 8°.

11. A display device, comprising a display panel, the display panel comprising an array substrate, an opposite substrate disposed opposite to the array substrate, and a liquid crystal layer disposed between the array substrate and the opposite substrate, the array substrate comprising:
a plurality of pixel units;
an alignment layer covering the pixel units and having an alignment direction parallel to a plane of the array substrate; and
a first electrode and a second electrode both disposed within each of the pixel units;
wherein, the first electrode has at least one branch electrode, the branch electrode has a first straight portion and a second straight portion, the first straight portion and the second straight portion are inclined inversely with respect to a direction perpendicular to the alignment direction, and an angle formed between the first straight portion and the alignment direction is larger than or equal to 5° and smaller than or equal to 8°.
